(19) United States
(12) Patent Application Publication
(10) Pub. No.: US 2010/0129060 A1
(43) Pub. Date: May 27, 2010

(54) DIGITAL BROADCAST RECEIVING APPARATUS AND METHOD

(75) Inventor: Choon-sik JUNG, Hwaseong-si (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/621,612

(22) Filed: Nov. 19, 2009

(30) Foreign Application Priority Data
Nov. 25, 2008 (KR) 10-2008-0117623

(51) Int. Cl. H04N 5/91; H03K 7/08

(52) U.S. Cl. 386/95; 375/238; 386/E05.003

(57) ABSTRACT

A digital broadcast receiving apparatus and a digital broadcast receiving method are provided. An oscillator changes a reference frequency of a system clock of the digital broadcast receiving apparatus using a PCR_{W}, which is a program clock reference (PCR) of a first transport stream, a record clock counter tunes a record arriving time clock (ATC) which is generated from the changed reference frequency and generates a tuned record ATC which is necessary to record a second transport stream different from the first transport stream, and a record stream interface adds a time stamp to the second transport stream using the tuned record ATC and outputs the second transport stream to a recording device.

### CROSS-REFERENCE TO RELATED APPLICATIONS

This application claims priority from Korean Patent Application No. 10-2008-117623, filed on Nov. 25, 2008, in the Korean Intellectual Property Office, the disclosure of which is incorporated herein by reference in its entirety.

### BACKGROUND OF THE INVENTION

1. Field of the Invention

Apparatuses and methods consistent with the present invention relate to digital broadcast receiving apparatus and method, and more particularly, to a digital broadcast receiving apparatus in which a user is able to watch a program while recording a different program using a single oscillator and a digital broadcast receiving method thereof.

2. Description of the Related Art

Recently, a digital broadcast receiving apparatus provides a function of reproducing an incoming transport stream to be watchable and simultaneously recording a different transport stream to a recording medium. In order to perform this function, the digital broadcast receiving apparatus accurately extracts a time stamp when recording and reproducing the transport streams and combines the time stamp with the transport streams, or extracts a time stamp from the transport streams. However, the function of reproducing a program and simultaneously recording a different program requires two clock sources (oscillators) since the two programs have different program clock references (PCR).

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

The an exemplary embodiment of the present invention provides a digital broadcasting apparatus which uses a single oscillator when reproducing and recording two or more different programs simultaneously, thereby providing a cost saving effect, and also minimizes a PCR jitter which may occur due to the use of a single oscillator, and a digital broadcasting method thereof.

Consistent with an aspect of the present invention, a digital broadcasting apparatus comprises an oscillator which changes a reference frequency of a system clock of the digital broadcasting apparatus using a PCR_{W}, which is a program clock reference (PCR) of a first transport stream, a record clock counter which tunes a record arriving time clock (ATC) which is generated from the changed reference frequency and generates a tuned record ATC which is necessary to record a second transport stream different from the first transport stream, and a record stream interface which adds a time stamp to the second transport stream using the tuned record ATC and outputs the second transport stream with the time stamp to a recording device.

The digital broadcasting apparatus may further comprise a controller which calculates a ratio which is necessary to generate the tuned record ATC using the generated record ATC and a PCR_{R} which is a PCR of the second transport stream.

The controller may latch the record ATC corresponding to the point of time that the PCR_{R} is input at least two times, and may calculate a ratio of a difference between the at least two latched record ATCs and a difference between the at least two PCR_{R}s as a ratio necessary to generate the tuned record ATC.

The record clock counter may generate the tuned record ATC using the following equation:

Tuned ATC(k)=ATC(k)×(PCRₙ−PCRₙ₋₁)/(ATCₙ−ATCₙ₋₁)

wherein the Tuned ATC(k) denotes a tuned record ATC, ATC(k) denotes the kth record ATC, PCRₙ denotes the nth PCR, ATCₙ denotes a ATC corresponding to the point of time that the PCRₙ is input, and k and n are constants.

The record stream interface may add the tuned record ATC corresponding to the point of time that the second transport stream is input as the time stamp.

The digital broadcasting apparatus may further comprise a system clock recovery device which generates a PWM signal which corresponds to a difference between a counting value of a system time counter (STC) generated from the system clock and the PCR_{W}, and recovers the system clock, and the oscillator may change the reference frequency of the system clock using the PWM signal.

The digital broadcasting apparatus may further comprise a de-multiplexer which selects one of the first transport stream which is being replayed and the second transport stream which is recorded to the recording device, and a decoder which decodes the selected one transport stream.

Consistent with another aspect of the present invention, a digital broadcasting method of a digital broadcasting apparatus, comprises changing a reference frequency of a system clock using a PCR_{W} which is a PCR of a first transport stream, tuning a record ATC which is generated from the changed reference frequency and generating a tuned record ATC which is necessary to record a second transport stream different from the first transport stream, and adding a time stamp to the second transport stream using the tuned record ATC and recording the second transport stream with the time stamp to a recording device.

The digital broadcasting method may further comprise calculating a ratio which is necessary to generate the tuned record ATC using the generated record ATC and a PCR_{R} which is a PCR of the second transport stream.

The calculating operation may comprise latching the record ATC corresponding to the point of time that the PCR_{R} is input at least two times, and calculating a ratio of a difference between the at least two latched record ATCs and a difference between the at least two PCR_{R}s as a ratio necessary to generate the tuned record ATC.

The operation of generating the tuned record ATC may use the following equation:

Tuned ATC(k)=ATC(k)×(PCRₙ−PCRₙ₋₁)/(ATCₙ−ATCₙ₋₁)

wherein the Tuned ATC(k) denotes a tuned record ATC, ATC(k) denotes the kth record ATC, PCRₙ denotes the nth PCR, ATCₙ denotes a ATC corresponding to the point of time that the PCRₙ is input, and k and n are constants.

The recording operation may add the tuned record ATC corresponding to the point of time that the second transport stream is input as the time stamp.

The digital broadcasting method may further comprise generating a PWM signal which corresponds to a difference between a counting value of a STC generated from the system clock and the PCR_{W}, and recovering the system clock, and the changing operation may change the reference frequency of the system clock using the PWM signal.

Consistent with still another aspect of the present invention, a digital broadcasting apparatus which records a second transport stream which is different from a first transport stream which is being replayed, comprises oscillator which changes a reference frequency of a system clock, a recording device which records the second transport stream, and a controller which, if a ratio of a difference between time stamps of the second transport stream recorded to the recording device and a difference between PCRs of the second transport stream is less than a reference value, determines that replaying and recording operations are simultaneously performed using the single oscillator.

Additional and/or other aspects of the invention will be set forth in part in the description which follows and, in part, will be obvious from the description, or may be learned by practice of the invention.

### BRIEF DESCRIPTION OF THE DRAWING FIGURES

The above and/or other aspects of exemplary embodiments of the present invention will be more apparent by describing certain exemplary embodiments of the present invention with reference to the accompanying drawings, in which:

FIG. 1 is a block diagram illustrating a digital broadcast receiving apparatus consistent with an exemplary embodiment of the present invention;

FIG. 2 is a view illustrating a process of generating a tuned record arriving time clock (ATC);

FIG. 3 is a flowchart illustrating a digital broadcast receiving method of a digital broadcast receiving apparatus consistent with an exemplary embodiment of the present invention;

FIG. 4 is a flowchart illustrating a method for recording a second transport stream (TS) to a recording device after operation 5360 of FIG. 3; and

FIG. 5 is a block diagram a digital broadcast receiving apparatus consistent with another exemplary embodiment of the present invention.

### DETAILED DESCRIPTION OF THE EXEMPLARY EMBODIMENTS

Certain exemplary embodiments of the present invention will now be described in greater detail with reference to the accompanying drawings.

In the following description, same drawing reference numerals are used for the same elements even in different drawings. The matters defined in the description, such as detailed construction and elements, are provided to assist in a comprehensive understanding of the invention. Thus, it is apparent that the exemplary embodiments of the present invention can be carried out without those specifically defined matters. Also, well-known functions or constructions are not described in detail since they would obscure the invention with unnecessary detail.

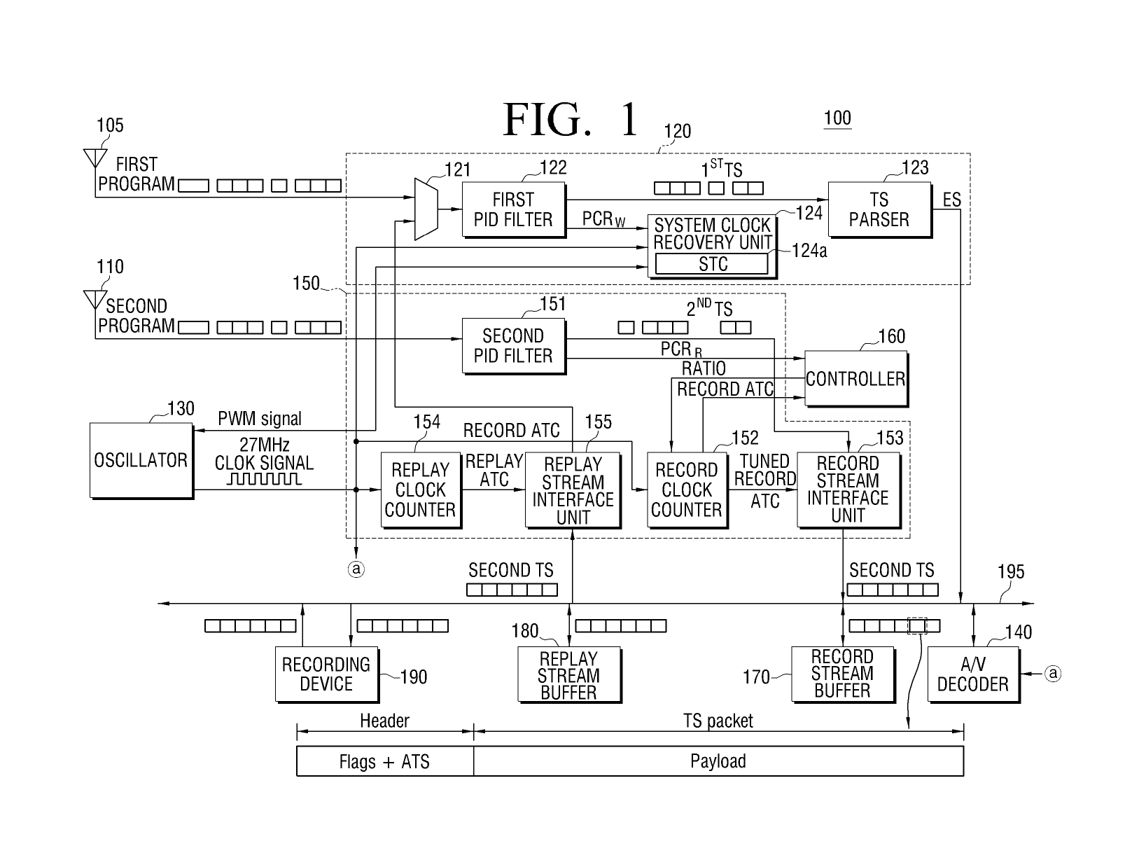

FIG. 1 is a block diagram illustrating a digital broadcast receiving apparatus consistent with an exemplary embodiment of the present invention. A digital broadcast receiving apparatus 100 shown in FIG. 1 may have a personal video recorder (PVR) function. The digital broadcast receiving apparatus 100 receives transport streams (TSs) conforming to the standard of moving picture experts group-2 (MPEG-2) and combines a time stamp which is information necessary for synchronization with each of the TSs when recording the received TSs to a recording device 190. The TS which has been recorded is synchronized and reproduced based on the time stamp.

Also, the digital broadcast receiving apparatus 100 reproduces a first program to be watched by a user and simultaneously records a second program to the recording device 190 using a single oscillator, that is, a single clock source.

The digital broadcast receiving apparatus 100 comprises a first receiver 105 and a second receiver 110, a first TS de-multiplexer 120, an oscillator 130, an audio/video (AV) decoder 140, a second TS de-multiplexer 150, a controller 160, a record stream buffer 170, and a replay stream buffer 180. Other components which are required to realize the present invention, such as a memory, a control program, and software, are omitted for convenience of explanation.

The recording device 190 may be provided in the digital broadcast receiving apparatus 100 if the digital broadcast receiving apparatus 100 is a PVR, or may be connected to the digital broadcast receiving apparatus 100 through a cable or a terminal.

The first receiver 105 receives a first program to be watched and the second receiver 110 receives a second program to be recorded. The first and the second receivers 105, 110 may be tuners or cable terminals which are connected to an external device. The first and the second receivers 105, 110 may receive multi-programs, respectively. That is, each of the first and the second receivers 105, 110 may receive two or more different programs, in which case a first packet ID (PID) filter 122 and a second PID filter 151 are capable of filtering desired first and second programs.

The first and the second programs consist of digital broadcast TSs which are MPEG-2 TSs, for example. The first and the second programs may be received through a single receiver but in this embodiment the first and the second programs are received through the two receivers 105, 110, respectively.

The first TS de-multiplexer 120 serves as a replay de-multiplexer for processing the received first program into signals which are capable of being watched or reproducing a program recorded in the recording device 190, and comprises a switch 121, the first PID filter 122, a TS parser 123, and a system clock recovery unit 124.

The switch 121 selects one of the first program received through the first receiver 105 and the second program stored in the recording device 190. The selected program may be selected by a user. Hereinafter, the case where the first program is selected will be described.

The first PID filter 122 filters the first program to extract a first TS which includes a PCR_{W}, which is a PCR (program clock reference, it also means reference clock counter or program clock counter) of the first program, and an AV signal. The first TS indicates a TS of the first program and the second TS indicates a TS of the second program.

The TS parser 123 parses the first TS to generate an AV elementary stream (ES) which is capable of being decoded.

The system clock recovery unit 124 comprises a system time counter (STC) 124a to count a system clock input from the oscillator 130, and performs a system clock recovery process using a difference between a counting result of the STC 124a and the PCR_{W}.

The system clock recovery means outputting a control signal corresponding to the difference so that the difference between the counting result and the PCR_{W} is equal to ‘0’. The control signal may be a PWM signal for example and may be input to the oscillator 130. The system clock recovery is performed every time that the PCR_{W} is filtered by and input from the first PID filter 122.

The oscillator 130 generates a reference clock, that is, a system clock corresponding to a reference frequency of the digital broadcast receiving apparatus 100, and transmits the system clock to the system clock recovery device 124. The reference frequency may be 27 MHz±αHz. Also, the oscillator 130 may change the reference frequency using the PCR_{W} which is included in the first TS of the first program.

That is, the oscillator 130 may change the reference frequency to synchronize the reference frequency with the first program using the PWM signal input from the system clock recovery device 124. The changed reference frequency is input to the system clock recovery device 124, the AV decoder 140, a record clock counter 152, or a replay clock counter 154.

The A/V decoder 140 decodes the ES of the first program which is input from the TS parser 123 to output watchable signals. The A/V decoder 140 adjusts a horizontal synchronization signal and a vertical synchronization signal of the ES using a clock (\textcircled{a}) of the reference frequency which is being changed by the oscillator 130.

The second TS de-multiplexer 150 serves as a record de-multiplexer for processing the second program into signals which are capable of being recorded, and comprises the second PID filter 151, the record clock counter 152, a record stream interface unit 153, the replay clock counter 154, and a replay stream interface unit 155.

The second PID filter 151 filters the second program input from the second receiver 110 to extract a second TS which includes a PCR_{R}, which is a PCR of the second program, and the AV signal.

The record clock counter 152 tunes a record arriving time clock (ATC) generated from the reference frequency changed by the oscillator 130 to generate a tuned record ATC which is necessary to record the second TS. A result of tuning the record ATC is the tuned record ATC which is necessary to record the second TS.

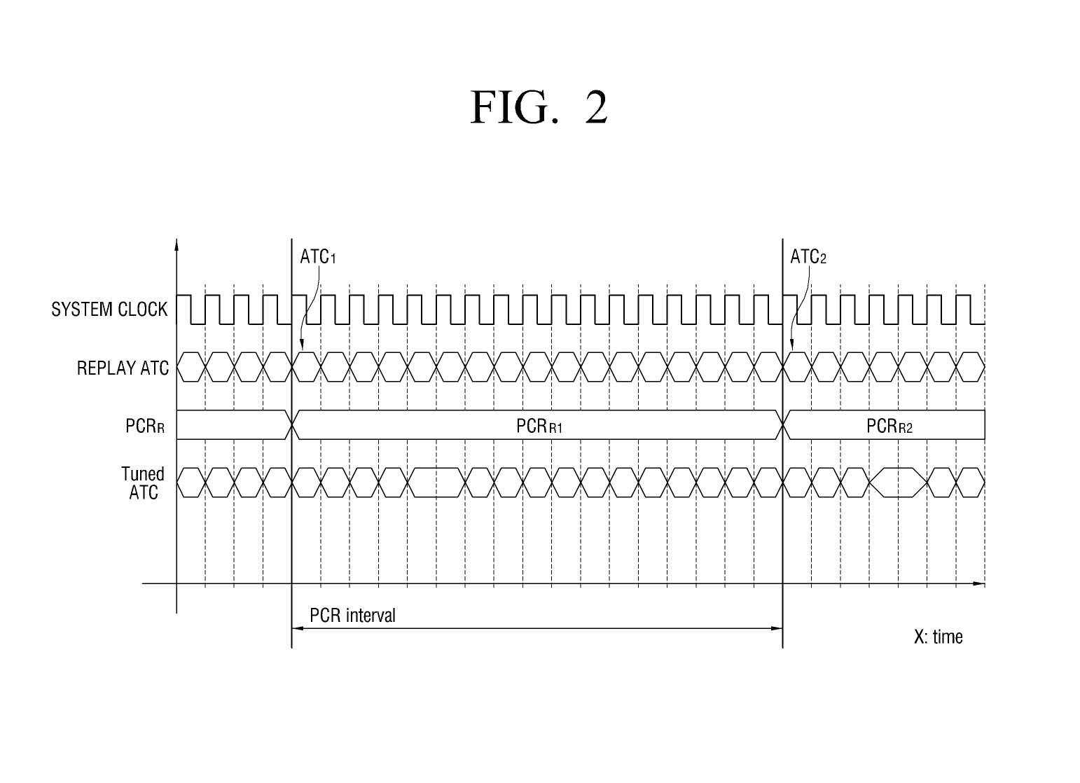

More specifically, if a system clock corresponding to the changed reference frequency is input as shown in FIG. 2, the record clock counter 152 generates a record ATC corresponding to the input system clock and counts the generated record ATC. The system clock corresponding to the changed reference frequency is a clock which is synchronized with the first program (that is, a watchable program).

The controller 160 calculates a ratio which is necessary to tune the record ATC generated by the record clock counter 152 and the PCR_{R} input from the second PID filter 151. Based on the calculated ratio, the controller 160 tunes an error of a record clock counter generated from the reference clock of the first program with respect to the reference clock of the second program, thereby generating the tuned record ATC as a result.

More specifically, the controller 160 latches the record ATC corresponding to the point of time that the PCR_{R} is input from the second PID filter 151 at least two times. The controller 160 calculates a difference between the at least two latched record ATCs and a difference between the at least two PCR_{R}s corresponding to the two latched record ATCs, and outputs a ratio of the two differences as a ratio for tuning the record ATC. Since the difference between the two PCR_{R}s, that is, the PCR interval, indicates a difference between the reference clocks of the second TS to be stored, or a difference between the reference clocks of the broadcasting station providing the second TS, the difference is used to calculate a tuned record ATC.

The controller 160 latches the record ATC corresponding to the PCR_{R}, records the latched record ATC to a memory (not shown) every time that the PCR_{R} is input from the second PID filter 151, and a previous PCR_{R} and a current PCR_{R}. This is because the current PCR_{R} and the previous PCR_{R} and their corresponding record ATCs are used to calculate the ratio.

Referring to FIG. 2, the controller 160 latches a counting value ATC₁ of the record ATC corresponding to the point of time that the PCR_{R1} is input from the second PID filter 151, and latches a counting value ATC₂ of the record ATC corresponding to the point of time that the PCR_{R2}, which is the next PCR_{R} of the PCR_{R1}, is input. The controller 160 subtracts the ATC₁ from the ATC₂, subtracts the PCR_{R1} from the PCR_{R2}, and then calculates a ratio of two subtracting results. Herein, PCR_{R1}, PCR_{R2}, ATC₁, ATC₂ may be expressed by counting values and may be recorded to the memory.

The record clock counter 152 multiplies the ratio for tuning which is calculated by the controller 160 with the record ATC to generate a tuned record ATC. That is, the tuned record ATC is a result of correcting the record ATC to be suitable for recording the second TS.

The record clock counter 152 generates a tuned record ATC using the record ATC based on the following equation:

Tuned ATC(k)=ATC(k)×(PCR_{Rn}−PCR_{Rn-1})/(ATCₙ−ATCₙ₋₁) [Equation 1]

wherein tuned ATC(k) denotes a tuned record ATC, which is a result of tuning the kth record ATC, ATC(k) denotes the kth record ATC, k denotes a counting value of the record ATC, PCR_{Rn} denotes the nth PCR, and ATCₙ denotes an ATC corresponding to the point of time that PCR_{Rn} is input.

Also, (PCR_{Rn}−PCR_{Rn-1})/(ATCₙ−ATCₙ₋₁) denotes a ratio which is necessary to tune the record ATC. The calculated ratio is same during the PCR interval and the ATC(k) progressively increases for each clock.

For example, if the calculated ratio is less than ‘1’, that is, if (PCR_{Rn}−PCR_{Rn-1}) is less than (ATCₙ−ATCₙ₋₁), the record clock counter 152 generates a tuned record ATC in which two or more clocks are counted as one clock as shown in FIG. 2. To the contrary, if the calculated ratio is greater than ‘1’, the record clock counter 152 generates a tuned record ATC in which one clock is counted two or more times.

Referring back to FIG. 1, the record stream interface unit 153 continuously receives the tuned record ATC (e.g., the tuned ATC of FIG. 2) from the record clock counter 152. The record stream interface 153 latches the tuned record ATC corresponding to the point of time that the second TS is input from the second PID filter 151, and adds the latched ATC to the second TS as an arriving time stamp (ATS), thereby generating a source packet. The ATS may be added to the payload of a TS as a header and may include flags.

The record stream interface 153 temporarily stores the second TS with the ATS to the record stream buffer 170, and then records the second TS to the recording device 190 through a data bus 195.

If a replay of the second TS recorded to the recording device 190 is requested, the controller 160 temporarily stores the second TS recorded to the recording device 190 to the replay stream buffer 180, and transmits the second TS which is temporarily stored to the replay stream interface 155 through the data bus 195.

The replay clock counter 154 receives the system clock from the oscillator 130 and generates the ATC through the free run. The free run refers to a process of continuously counting the record ATC from an initial value (for example, ‘0’).

The replay stream interface 155 outputs the second TS to the switch 121 if a replay ATC input from the replay clock counter 154 is identical to the time stamp of the second TS, that is, the ATS, which is input from the replay stream buffer 180. The switch 121 switches to the second TS and transmits the second TS to the first PID filter 122.

After that, the system clock recovery device 124 generates a control signal such as a PWM signal based on the PCR_{R} of the second TS and the reference frequency, and the oscillator 130 synchronizes the reference frequency with the second TS using the control signal. The synchronized reference frequency, that is, the changed reference frequency is input to the replay clock counter 154 such that the above operation is repeated.

As described above, the oscillator 130 for replaying a program can be used to adjust the reference frequency and generate the time stamp necessary to record the second TS. To this end, an oscillator for recording a program is not additionally required so that an additional cost cannot be incurred, and also, since it is possible to generate a tuned record ATC, a jitter can be prevented.

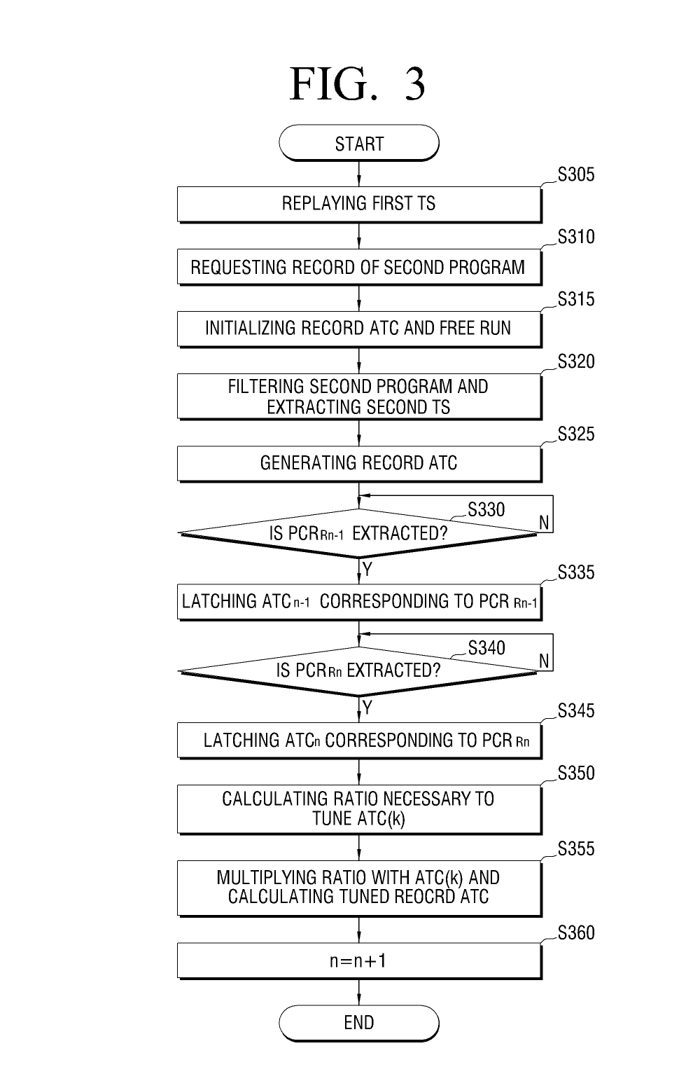

FIG. 3 is a flowchart illustrating a digital broadcast receiving method of the digital broadcast receiving apparatus consistent with an exemplary embodiment of the present invention.

Referring to FIGS. 1 to 3, when the first TS of the first program is replayed as watchable signals (S305), if a record of the second program is requested (S310), the record clock counter 152 initializes a record ATC and performs the free run (S315).

The second PID filter 151 filters the second program received through the second receiver 110 and extracts the second TS (S320).

The record clock counter 152 receives a reference frequency which is changed by the oscillator 130, and generates a record ATC and transmits the record ATC to the controller 160 (S325).

If the PCR_{Rn-1} is extracted by the second PID filter 151 (S330), the controller 160 latches the record ATCₙ₋₁ corresponding to the PCR_{Rn-1} at the record ATC input in operation S320 (S335).

If the PCR_{Rn}, which is the next PCR_{R}, is extracted by the second PID filter 151 (S340), the controller 160 latches the record ATCₙ corresponding to the PCR_{Rn} at the record ATC input in operation S320 (S345).

The controller 160 calculates a ratio which is necessary to tune the ATC(k) using the PCR_{Rn-1}, PCR_{Rn}, ATCₙ₋₁, ATCₙ which are obtained in operations S330 to S345 (S350), wherein the ATC(k) denotes a counting value of the kth record ATC.

The record clock counter 152 multiplies the ratio calculated in operation S350 with the ATC(k), calculates a tuned record ATC, and transmits the tuned record ATC to the record stream interface 153 (S355).

If the next PCR_{R} is extracted by updating to n=n+1, the controller 160 repeats operations S335 to S355 (S360).

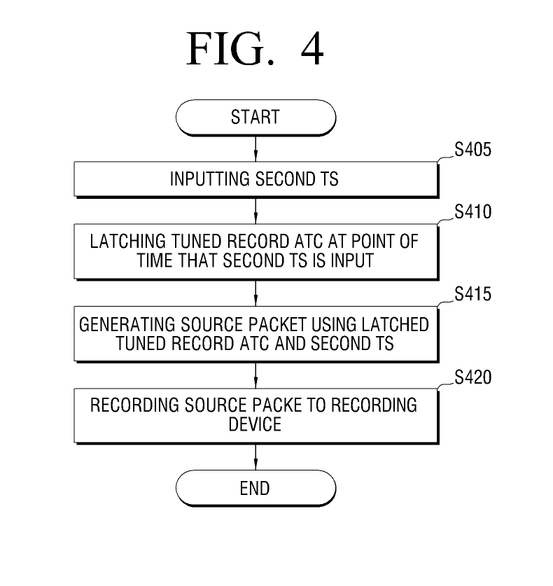

FIG. 4 is a flowchart illustrating a method for recording the second TS to the recording device after operation S360.

If the second TS is input to the record stream interface 153 (S405), the record stream interface 153 latches the tuned record ATC which corresponds to the point of time that the second TS is input (S410).

The record stream interface 153 generates a source packet shown in FIG. 2 using the tuned record ATC which has been latched in operation S410 and the second TS (S415).

The controller 160 controls the record stream interface 153 to temporarily store the source packet to the record stream buffer 170 and then record it to the recording device 190 (S420).

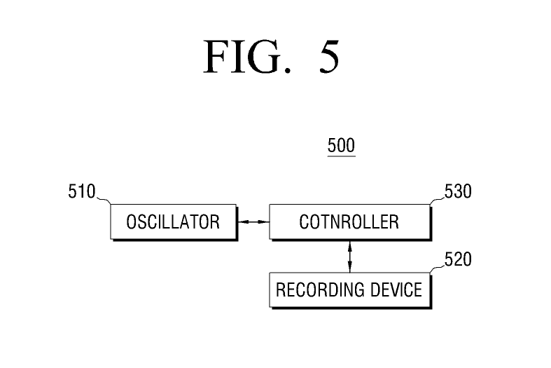

FIG. 5 is a block diagram illustrating a digital broadcast receiving apparatus consistent with another exemplary embodiment of the present invention.

Although a digital broadcast receiving apparatus 500 of FIG. 5 may perform the same function as the digital broadcast receiving apparatus 100 of FIG. 1, detailed illustration and description are omitted for the sake of simplicity. The digital broadcast receiving apparatus 500 is capable of replaying a first TS corresponding to a first channel and simultaneously recording a second TS corresponding to a second channel using a single oscillator 510.

The oscillator 510 shown in FIG. 5 changes a reference frequency set in the digital broadcast receiving apparatus 500 by synchronizing the reference frequency with the first TS. To this end, the system clock corresponding to the reference frequency is utilized in replaying the first TS or recording the second TS.

A recording device 520 records the second TS which is requested to be recorded. The recording device 520 may be provided in the digital broadcast receiving apparatus 500 or may be an external recording medium which is removably mounted on the digital broadcast receiving apparatus 500. The second TS is allocated a time stamp in the method described above with reference to FIGS. 1 to 3.

If a ratio of a difference between the time stamps of the second TS recorded to the recording device 520 and a difference between the PCRs of the second TS is less than a reference value, the controller 530 determines that the digital broadcast receiving apparatus 500 simultaneously replays and records different programs using the single oscillator 510. The reference value is stored to a memory (not shown) and may be ‘1’. That is, the controller determines whether to use the single oscillator 510 by determining whether the value

$$( \frac{Difference between P C R s}{Difference between time stamps} )$$

is less than 1.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A digital broadcast receiving apparatus comprising:
an oscillator which changes a first reference frequency of a system clock of the digital broadcast receiving apparatus using a program clock reference of a first transport stream (PCR_{W}), to a second reference frequency;
a record clock counter which tunes a record arriving time clock (ATC) which is generated from the second reference frequency and generates a tuned record ATC to record a second transport stream; and
a record stream interface which adds a time stamp to the second transport stream using the tuned record ATC and outputs the second transport stream with the time stamp to a recording device.

2. The digital broadcast receiving apparatus as claimed in claim 1, further comprising a controller which calculates a ratio to generate the tuned record ATC and a PCR of the second transport stream (PCR_{R}).

3. The digital broadcast receiving apparatus as claimed in claim 2, wherein the controller latches the record ATC corresponding to a point of time that the PCR_{R} is input at least two times to have at least two latched record ATCs and at least two PCR_{R}s, and calculates a ratio of a difference between the at least two latched record ATCs and a difference between the at least two PCR_{R}s as the ratio to generate the tuned record ATC.

4. The digital broadcast receiving apparatus as claimed in claim 2, wherein the record clock counter generates the tuned record ATC using the following equation:
Tuned ATC(k)=ATC(k)×(PCRₙ−PCRₙ₋₁)/(ATCₙ−ATCₙ₋₁)
wherein the Tuned ATC(k) denotes the tuned record ATC, ATC(k) denotes a kth record ATC, PCRₙ denotes an nth PCR, ATCₙ denotes an ATC corresponding to a point of time that the PCRₙ is input, and k and n are constants.

5. The digital broadcast receiving apparatus as claimed in claim 1, wherein the record stream interface adds the tuned record ATC corresponding to the point of time that the second transport stream is input as the time stamp.

6. The digital broadcast receiving apparatus as claimed in claim 1, further comprising a system clock recovery device which generates a pulse width modulated (PWM) signal which corresponds to a difference between a counting value of a system time counter (STC) generated from the system clock and the PCR_{W}, and recovers the system clock,
wherein the oscillator changes the first reference frequency of the system clock using the PWM signal.

7. The digital broadcast receiving apparatus as claimed in claim 1, further comprising a de-multiplexer which selects one of the first transport stream which is being replayed and the second transport stream which is recorded to the recording device; and
a decoder which decodes the selected one of the first transport stream which is being replayed and the second transport stream which is recorded to the recording device.

8. A digital broadcast receiving method of a digital broadcast receiving apparatus, the digital broadcast receiving method comprising:
changing a first reference frequency of a system clock using a program clock reference of a first transport stream (PCR_{W}), to a second reference frequency;
tuning a record arriving time clock (ATC) which is generated from the second reference frequency and generating a tuned record ATC to record a second transport stream; and
adding a time stamp to the second transport stream using the tuned record ATC and recording the second transport stream with the time stamp in a recording device.

9. The digital broadcast receiving method as claimed in claim 8, further comprising calculating a ratio to generate the tuned record ATC and a PCR of the second transport stream (PCR_{R}).

10. The digital broadcast receiving method as claimed in claim 9, wherein the calculating operation comprises:
latching the record ATC corresponding to a point of time that the PCR_{R} is input at least two times to have at least two latched record ATCs and at least two PCR_{R}s; and
calculating a ratio of a difference between the at least two latched record ATCs and a difference between the at least two PCR_{R}s to generate the tuned record ATC.

11. The digital broadcast receiving method as claimed in claim 9, wherein the operation of generating the tuned record ATC uses the following equation:
Tuned ATC(k)=ATC(k)×(PCRₙ−PCRₙ₋₁)/(ATCₙ−ATCₙ₋₁)
wherein the Tuned ATC(k) denotes the tuned record ATC, ATC(k) denotes a kth record ATC, PCRₙ denotes an nth PCR, ATCₙ denotes an ATC corresponding to a point of time that the PCRₙ is input, and k and n are constants.

12. The digital broadcast receiving method as claimed in claim 8, wherein the recording operation adds the tuned record ATC corresponding to the point of time that the second transport stream is input as the time stamp.

13. The digital broadcast receiving method as claimed in claim 8, further comprising generating a pulse width modulated (PWM) signal which corresponds to a difference between a counting value of a STC generated from the system clock and the PCR_{W}, and recovering the system clock,
wherein the changing operation changes the first reference frequency of the system clock using the PWM signal.

14. A digital broadcast receiving apparatus which records a second transport stream while a first transport stream is being replayed, the digital broadcast receiving apparatus comprising:
an oscillator which changes a reference frequency of a system clock;
a recording device which records the second transport stream; and
a controller which, if a ratio of a difference between time stamps of the second transport stream recorded to a recording device and a difference between program clock references (PCRs) of the second transport stream is less than a reference value, determines that replaying and recording operations are simultaneously performed using the oscillator.

15. A digital broadcast receiving method of a digital content processing device receiving substantially simultaneously a first transport stream (TS) and a second TS, the method comprising:
replaying the first TS;
modifying a first frequency of a single clock source of the digital content processing device using information from a first transport stream, to a second frequency;
generating a record arriving time clock (ATC) from the second frequency; and
adding a time stamp to the second TS using the record ATC and recording the second TS with the time stamp in a recording device;
wherein the replaying the first TS and the recording the second TS with the time stamp in the recording device are substantially simultaneously performed.

16. The digital broadcast receiving method of claim 15, wherein the replaying the first TS and the recording the second TS with the time stamp in the recording device are both based on operations of the single clock source.

17. The digital broadcast receiving method of claim 16, wherein the single clock source is a single oscillator.
